(19) United States
(12) Patent Application Publication
(10) Pub. No.: US 2004/0169185 A1
(43) Pub. Date: Sep. 2, 2004

(54) High luminescent light emitting diode

(76) Inventor: Heng Liu, Sunnyvale, CA (US)

Correspondence Address: Norman E. Carte, Myers Dawes Andras & Sherman LLP, Suite 1150, 19900 MacArthur Blvd,, Irvine, CA, 92612, US

(21) Appl. No.: 10/377,186

(22) Filed: Feb. 28, 2003

(51) Int. Cl. H01L 33/00

(52) U.S. Cl. 257/96

(57) ABSTRACT

A method for dicing a wafer includes providing a wafer formed of a material having a crystal structure which facilitates breaking of the wafer in a substantially consistent and desirable manner without thinning thereof. For example, a wafer formed of Spinal may be used to form die having a thickness greater than 200 micrometers, such that a high luminance AlInGaN based light emitting diode can be formed thereon.

### FIELD OF THE INVENTION

The present invention relates generally to light emitting diode (LED) fabrication methodology. The present invention relates more particularly to a method for dicing wafers which facilitates the use of thicker device substrates, so as to enhance the luminescence of LEDs fabricated therefrom and to an enhanced luminance LED having a thick substrate and a reflector formed on the back side thereof.

### BACKGROUND OF THE INVENTION

Light emitting diodes (LEDs) for use as indicator lights, for providing illumination, and for various other purposes are well known. Although contemporary LEDs have proven generally suitable for their intended purposes, they possess inherent deficiencies which detract from their overall effectiveness and desirability. For example, the illumination provided by contemporary LEDs is not as much as is sometimes desired. Undesirable limitations are placed upon the amount of illumination provided by an LED by, among other things, the thickness of the LED die.

As those skilled in the art will appreciate, the thicker that an LED's epitaxial layer is, the more light that can be transmitted therethrough. That is, more light ultimately escapes from a thicker LED epitaxial layer than from a thinner one. Thus, LEDs with thicker epitaxial layers tend to be desirably brighter than LEDs with thinner ones. This has been demonstrated in the AlInGaP based LEDs where a thick GaP window layer of several tens of microns is used to enhanced the light extraction from the side of the epitaxial layer. In the case of AlInGaN based LEDs, the AlInGaN layers defining the LED structure are epitaxially typically deposited on sapphire (Al₂O₃).

However, the issue of light extraction from sapphire is different from that of many other substrates. Since sapphire is transparent, a significant portion of light goes into the substrate. Thus, in addition to the thickness of the epitaxial layers, the thickness of the substrate can also have an impact on the amount of light being extracted. Therefore, it such instances, it is desirable to have thick transparent substrate for better light output efficiency.

A contemporary device structure having a sapphire substrate is shown in FIG. 1. The LED structure has multiple layers that are epitaxially deposited on the sapphire substrate 15 via a metal organic chemical vapor deposition (MOCVD) process. The layers include n-type AlInGaN 14 formed upon the sapphire substrate 15, an active region 13 formed upon the n-type AlInGaN 14, p-type AlInGaN 16 formed upon the active region 13, a transparent ohmic contact to p-AlInGaN 12 formed upon the active region 13 and an ohmic contact to n-AlInGaN 11.

The sapphire substrate typically comes in a 2″ round disk with about a 400 microns thickness. LED layers are much thinner. They are only a few micrometers thick. Once the LED layers are deposited, the wafer is subjected to processes that form individual LED devices on the wafer. The wafer is then thinned and diced into individual LED dies.

Since sapphire is so hard and has a six-fold symmetry, it is very difficult to make the right angle cuts which are necessary to form a rectangular die. Typically, one set of cleavage planes can be used to reliably make one set of well defined cuts with sapphire. However, sapphire's six-fold symmetry does not provide a second set of cleavage planes which is perpendicular to the first set. Thus, the second set of cuts will tend to be less well defined and less satisfactory when forming square die.

Usually, a sapphire wafer needs to be thinned down to less than 100 microns in order to dice it into rectangular die with reasonable yield. It is possible to use, for example, focused high power laser to cut thicker than 100 microns sapphire. The technique, however, is not yet known to be a mature manufacturing approach yet, especially for sapphire thicker than 120 micron. During the sapphire thinning process, stress builds up and frequently causes the wafer to bow and possibly to break, thus making the subsequent dicing process difficult. Further yield loss often occurs due to these factors. Additionally, current dicing techniques employ scribe-and-break methodology using diamond tips which are very expensive.

Since sapphire must typically be thinned to less than 100 micrometers, LED substrates formed of sapphire do not tend to maximize the amount of light which escapes therefrom and thus the use of sapphire does not generally facilitate the fabrication of LEDs which are comparatively bright.

Since sapphire is transparent to visible light, light generated from the active region of the LED structure propagates not only through the top and the sides of the device, but also through the substrate, including the sides of the substrate. This ability to allow light to escape from the device makes sapphire a desirable material for use as a substrate. However, it has been shown by various research groups that the light generated inside the LED device can be trapped and lost due to total internal reflection and absorption.

As mentioned above, by increasing the thickness of the device layer as well as the substrate, light escaping from the sides can be increased. Therefore, it is desirable to have thicker substrate which is transparent. Using sapphire, according to contemporary fabrication methodology, as the substrate material limits the ability to fabricate a thicker substrate and therefore limits the light output efficiency. However, using sapphire according to methodology which facilitates the formation of a substrate having a thickness greater than 100 microns can facilitate the fabrication of an LED having enhanced brightness.

Moreover, it is desirable to provide materials and fabrication techniques which facilitate the manufacture of LEDs have thicker substrates than contemporary LEDs.

Before a LED die can be used, it must be packaged into lamp with leads for electrical contacts and optics for a desirable light emission pattern. In any package, the LED die first needs to be attached to the lead frame by die-attach epoxy. The epoxy is sometimes light absorbing, thereby causing undesirable light loss.

If transparent epoxy is used, most substrate light propagates through the epoxy and is then reflected by the coating of the lead frame. The reflected light either re-enters the LED die or is reflected back by the backside (substrate) of the die. In either case some portion of the light is lost due to internal absorption in the LED die and the epoxy when light is reflected in these regions. One current attempt to remedy to this situation is to coat a reflective layer on the backside of the die. The reflective coating can be metal such as Al, Ag, Cr, or any dielectric mirror. This is especially useful in a surface mount package, where focusing optics are not normally used. The reflective coating can help direct most of the light upward and therefore enhance the on-axis brightness of the package.

A schematic diagram of a typical surface mount LED package is shown in FIG. 2. This drawing can be either for a contemporary surface mount LED or for a surface mount LED of the present invention, wherein an LED die comprised of a Spinel substrate, for examples, is utilized. The LED die 23 is disposed within a casing 22 and covered with a transparent encapsulent 21. Two electrodes 24 and 25 provide electrical contact via contact wires 26 and 27 to the LED die 23.

However, coating the reflective layer on the backside of the LED die is not an easy task in the case of sapphire. The layer needs to be coated after the wafer is thinned. As mentioned earlier, the wafer can be bowed or sometimes even broken after thinning, thus making the coating process very difficult. Therefore, the wafer needs to remain on the lapping chuck, which is then mounted inside the metalization system, such as an e-beam evaporator for metal coating, or a sputtering system for dielectric coating. In the case of dicing from the backside, the wafer, with the lapping chuck, needs to go through a photolithographic step so that the dicing street on the front side remains visible from the backside without being covered by the reflective coating.

It is very important that the wafer not break on the chuck at this point during the thinning process. Otherwise, the necessary precise alignment between the front side device and the backside mirror pattern cannot be achieved. In order to ensure minimum breakage, lapping needs to be done very slowly, which undesirably reduces production throughput. Handling of the bulky lapping chuck, especially hundreds of them on a daily basis, is a very time consuming and labor intensive process, which undesirably increases cost.

The above described situation becomes even more severe when the wafer size increases. However, due to cost considerations, it is always desirable to use a larger size wafer, since fewer wafers are then needed for a given volume of throughput and more devices can be yielded on a per area basis due to less edge loss. The above described handling issues inhibit the use of the mirror process in larger size wafer manufacturing, such as for 3″ and 4″ wafers.

As such, although the prior art has recognized, to a limited extent, the problem of insufficient illumination from LEDs, the proposed solutions have, to date, been ineffective in providing a satisfactory remedy. Therefore, it is desirable to provide a method for forming an LED having a comparatively thick substrate, such that illumination provided thereby is enhanced with respect to conventional LEDs. It is also desirable to enhance the illumination provided by an LED by other means, such as via the use of a substrate mirror process that is compatible for use with such thicker substrates and which mitigates the undesirable loss of light through the backside of the substrate.

### SUMMARY OF THE INVENTION

The present invention specifically addresses and alleviates the above mentioned deficiencies associated with the prior art. More particularly, the present invention comprises an improved method for dicing a wafer. The method comprises providing a wafer formed of a material having a crystal structure which facilitates breaking of the wafer in a substantially consistent and desirable manner without significant thinning thereof. Since heavy thinning is not required, LEDs formed upon the wafer have thicker substrates and consequently enhanced illumination.

These, as well as other advantages of the present invention, will be more apparent from the following description and drawings. It is understood that changes in the specific structure shown and described may be made within the scope of the claims, without departing from the spirit of the invention.

### BRIEF DESCRIPTION OF THE DRAWINGS

FIG. 1 is a schematic representation of a typical LED structure deposited upon a sapphire substrate according to contemporary methodology;

FIG. 2 is a schematic representation of a typical surface mount LED package according to either contemporary methodology or according to the present invention, depending upon whether the LED die has a contemporary sapphire substrate or has a Spinel substrate of the present invention;

FIG. 3 is a schematic representation of the present invention showing a preferred AlInGaN LED device structure formed upon a transparent substrate with a cubic crystal structure and having a backside (bottom) reflector;

FIG. 4 is a perspective view of a Spinel wafer showing the square projections of the cleavage planes onto the top surface thereof; and

FIG. 5 is a side view of an LED which is enclosed within a housing and which has a focusing lens.

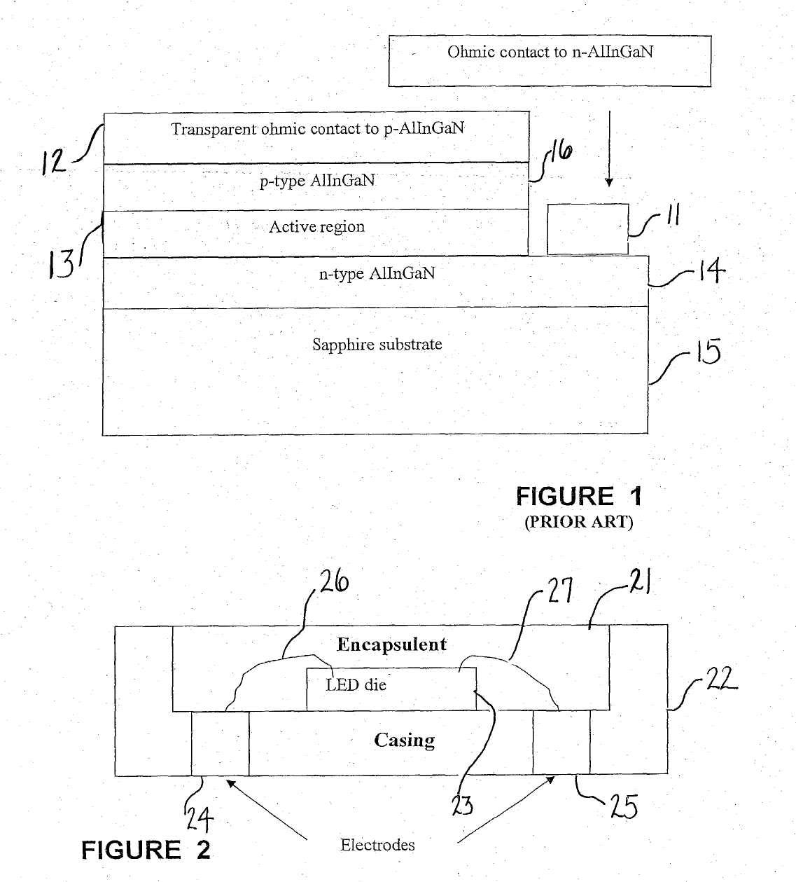

### DETAILED DESCRIPTION OF THE INVENTION

The detailed description set forth below in connection with the appended drawings is intended as a description of the presently preferred embodiments of the invention and is not intended to represent the only forms in which the present invention may be constructed or utilized. The description sets forth the functions and the sequence of steps for constructing and operating the invention in connection with the illustrated embodiments. It is to be understood, however, that the same or equivalent functions may be accomplished by different embodiments that are also intended to be encompassed within the spirit of the invention.

The present invention comprises a device structure of an AlInGaN based LED, the device structure comprising an epitaxially grown AlInGaN based multi-layered LED structure which is in direct connection to a thick transparent substrate. The total thickness of the LED is preferably at least approximately 110 microns thick and is preferably between approximately 200 microns and approximately 300 microns thick. However, as those skilled in the art will appreciate, the device may be of any desired thickness. The LED can have a backside reflector to enhance the on-axis intensity. The reflector is a coating of metallic film or a dielectric mirror.

The method to produce the above device structure can vary with the type of substrate material used. When the substrate is hexagonal symmetry such as sapphire, SiC, GaN, AlGaN, the LED die can be rectangular or square by cutting one set of cleavage planes and one set of non-cleavage planes perpendicular to the first set. The die can be parallelogram shape by cutting two sets of cleavage planes. On the other hand, when the substrate material has cubic symmetry, such as Spinel, ZnO, MgO, then the LED die can be fabricated so as to be rectangular or square by cutting two sets of cleavage planes. Cutting a cleavage plane normally is much easier than a non-cleavage plane. This is especially critical when cutting a thicker wafer. In the spirit of the discussion so far, therefore, the present invention comprises the method of providing an AlInGaN LED wafer formed of a substrate material having a crystal structure which facilitates breaking of the wafer in a substantially consistent and desirable manner without significant thinning thereof. The wafer is preferably at least approximately 110 microns thick before dicing and is preferably between approximately 200 microns and approximately 300 microns thick. However, as those skilled in the art will appreciate, the wafer may be of any desired thickness.

The AlInGaN LED wafer is formed of a substrate material having a crystal structure which tends to facilitate propagation of cracks therethrough from one surface (such as the back surface) to the other surface (such as the front surface) thereof. The cracks may propagate in a generally vertical (perpendicular to the two flat surfaces) fashion with respect to the wafer. Alternatively, the cracks may propagate at a non-orthogonal angle with respect to the two flat surfaces of the wafer. For example, when a Spinel wafer is utilized, the cracks will propagate at an angle of approximately 55 degrees with respect to the flat surfaces of the wafer. As those skilled in the art will appreciate, the cracks can propagate at a wide range of angles and still provide the desired result of generally rectangular, preferably square die.

Thus, when the wafer is broken during the dicing process, the breaks tend to be along the cleavage planes and thus extend between the top and bottom surfaces of the wafer.

Dicing the wafer typically comprises either mechanically scribing the wafer and breaking wafer, or alternatively laser scribing the wafer and breaking wafer.

Preferably, the crystal structure includes a plurality of cleavage planes which define a generally polygonal pattern when projected upon a surface of the wafer. Preferably, the plurality of cleavage planes define a generally quadralateral pattern when projected upon a surface of the wafer. Preferably, the plurality of cleavage planes define a generally parallelogram pattern when projected upon a surface of the wafer. Preferably, the plurality of cleavage planes defines a generally rhombic pattern when projected upon a surface of the wafer. Preferably, the plurality of cleavage planes defines a generally rectangular pattern when projected upon a surface of the wafer. Preferably, the plurality of cleavage planes defines a generally square pattern when projected upon a surface of the wafer.

Since one reason for providing a thicker substrate for LEDs and the like is to enhance their illumination by providing a better path for light to escape from the device, the path (which is defined by the substrate) should be as transparent at the desired wavelength as possible. Typically, it is desirable to make the substrate substantially transparent to visible light. Providing a thicker substrate also has other benefits. For example, a thicker substrate makes devices more durable and thus less susceptible to damage during handling, assembly, storage and transportation.

The crystal structure is preferably generally cubic and is preferably face centered cubic. Since the material is preferably transparent to visible light, examples of suitable material include MgO, ZnO and Spinel (MgAlO₃). However, this invention also applies to non-cubic material that is transparent such as AlN, GaN, AlGaN, 4H—SiC, 6H—SiC and sapphire.

Thus, according to one aspect, the present invention comprises a method for forming a AlInGaN based LED, the method comprising providing a substrate, the substrate comprising a crystalline material which has a crystal structure, the crystal structure defining at least two orthogonal cleavage planes which extends between the two flat surfaces of the wafer and which facilitates the formation of die having a desired geometric configuration and the substrate being substantially transparent to light of at least one wavelength, forming a plurality of separate LED structures upon the substrate, and dicing the substrate.

The LED is preferably formed upon the substrate via a metal organic chemical vapor deposition process. However, as those skilled in art will appreciate, various other methods for forming the LED upon the substrate are likewise suitable.

Optionally, the LED (including the substrate) is packaged into a lamp having leads configured to provide electrical power to the LED and having optics configured to provide a desired light emission pattern. Optionally, a reflective coating is formed on the bottom of the substrate. The reflective coating preferably comprises aluminum, silver, chromium or a dielectric material. As those skilled in the art will appreciate, other materials are likewise suitable.

The reflective coating is preferably formed on the bottom of the substrate before dicing the substrate, as discussed in further detail below. However, the reflective coating may alternatively be formed upon the bottom of the substrate after dicing the substrate.

According to one aspect, the present invention comprises a surface mount device comprising an AlInGaN based LED having a substrate, the substrate having a thickness greater than 110 micrometers and being substantially transparent to light of at least one wavelength, a casing within which the LED is substantially disposed, and leads extending into the casing and configured to provide electrical power to the LED. The LED preferably has a reflective coating formed upon the bottom thereof.

One way to attempt to provide thicker substrates for rectangular or square AlInGaN based LED dies and the like is to find a way to cut thicker sapphire wafers along one cleavage plane and an orthogonal non-cleavage plane. Usually, a lapping thickness of the wafer greater than 120 micrometers is necessary in order avoid breakage during the thinning process. However, at this thickness bowing still occurs. In order to avoid both breakage and bowing, a thickness greater than 150 micrometers is usually required. These data are determined empirically and are associated with current known thinning process.

However, so far there is no known dicing process that can achieve high enough yield and quality of cut for thickness greater than 110 micrometers. Recently, many vendors have reported good results using high power UV laser to create scribed grooves on sapphire to facilitate die separation by breaking through the grooves. The advantage of this procedure is to achieve cost savings with respect to diamond tip consumption.

The laser grooving is usually done on the backside of the sapphire to avoid debris redeposit on the devices fabricated on the front side (the epi side). However, breaking through the groove is not always vertical. When that happens, the break line could actually cut into devices on the front side, resulting in yield loss. This issue becomes worse as the thickness increases since more lateral shift of break line results. Additionally, the thicker the sapphire is the deeper the laser groove needs to be, resulting in a slower laser scribing rate and lower throughput. So far, this technique is optimized for sapphire thickness around 100 micrometers, which is similar to scribe-and-break technique.

Another approach is to grow the AlInGaN based LED structure on other types of substrates which are easier to dice and which do not require thinning as much as sapphire. According to the present invention, one preferred choice is to use a material with cubic crystal structure, so that it is easy to obtain a right angle cut, since the break line can be right on the cleavage plane of the crystal.

Candidates of materials having such cubic crystal structures which are also suitable for GaN epitaxy include, for example, GaAs, Si, MgO, ZnO, and Spinel. Since the substrate material also needs to be transparent for the device shown in FIG. 2 to function as desired, the choice is limited to MgO, ZnO, Spinel, and other substantially transparent cubic structures.

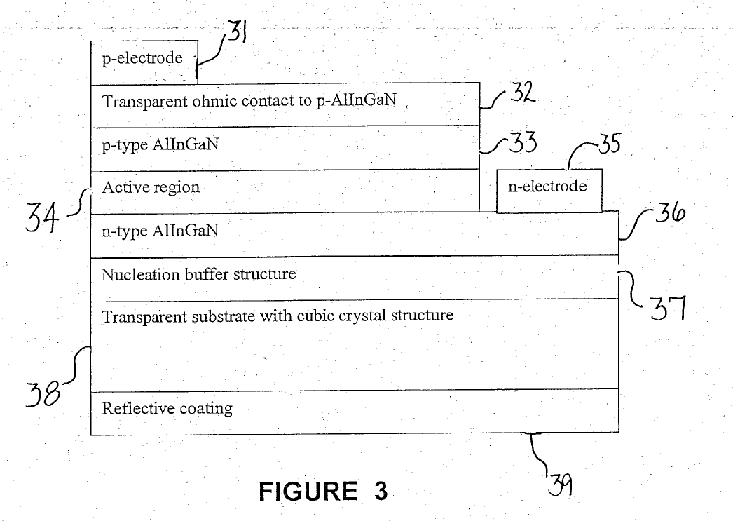

As shown in FIG. 3, according to the present invention the substrate material is transparent and has a cubic crystal structure. Although such transparent materials are not generally as hard as sapphire and are thus easier to dice, they still need to be thinned down before dicing. However, because of their cubic crystal structure such material doesn't have to be thinned down to 100 micrometers. Because of this advantage, the device shown in FIG. 3 can be much more easily produced in large volume. Wafer breakage and bowing can be better avoided during the lapping process.

Also, with such thicker substrates, light output efficiency of the LED is enhanced. Preferably, thickness up to 300 micrometers are used.

According to one aspect, the present invention comprises an AlInGaN LED, such as that shown in FIG. 3. The illustrated AlInGaN LED is a p-side up structure comprising a nucleating buffer structure 37 disposed on the substrate 38, an epitaxial layer comprising an n-type layer 36, an active region 34 and a p-type layer 33, a transparent or semi-transparent ohmic contact 32 on the p-type layer 33 and an ohmic contact 35 on the n-type layer 36, and a reflective coating layer 39 on the backside of the substrate 38. For a substrate material having a cubic structure, (111) orientation is usually preferred.

The n-type ohmic contact material is preferably Ti/W or Ti/Al. Material suitable for the reflective coating includes Al, Ag, Cr, and any metallic coating that has reflectivity to visible light in excess of 50%. The reflective coating can also be a dielectric mirror. The active region 34 can be a double heterostructure (DH), a single quantum well (SQW), or a multiple quantum well (MQW) structure. The n-type 36 and p-type 33 layers can be n-doped and p-doped AlₓIn_{y}Ga_{1-x-y}N, 0≦x,y≦1.

The present invention provides a method for fabricating an AlInGaN LED, which comprises the steps of providing a substrate that is transparent, has a cubic crystal structure, and is suitable for GaN epitaxy. An epitaxial structure is deposited on the substrate. The epitaxial structure has a plurality of III-nitride compound semiconductor layers that can generate light when electrical current is injected thereinto. An etching procedure exposes the n-type III-nitride layer for forming the n-type ohmic contact. Transparent or semi-transparent p-type ohmic contact is deposited upon the p-type III-nitride layer. The back side of the wafer is thinned down and polished to a thickness greater than 120 micrometers. Reflective coating is deposited on the polished backside of the substrate.

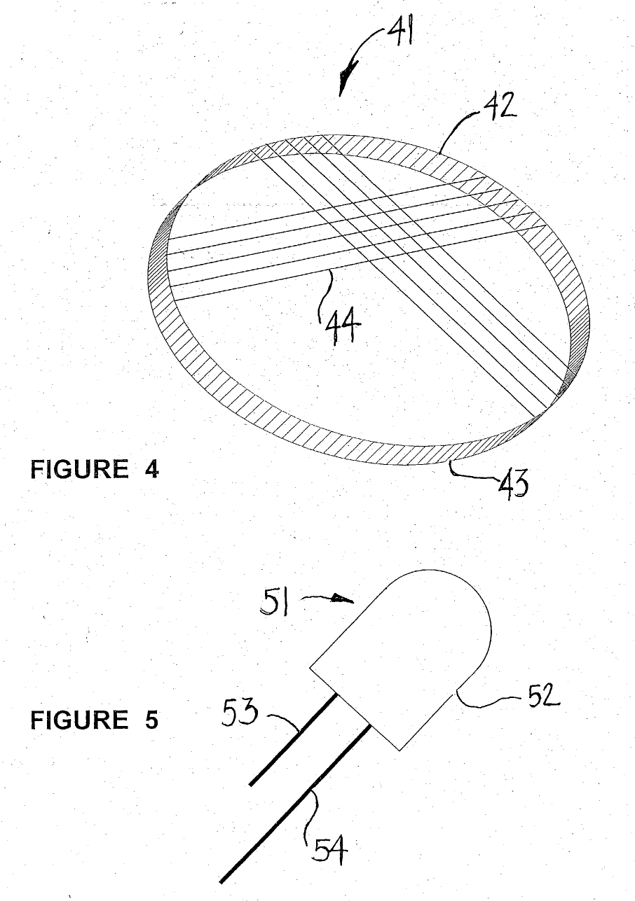

Referring now to FIG. 4, a wafer 41 has a generally flat top 42 and a generally flat bottom 43. Cleavage planes are projected from the crystal structure within the wafer 41 onto the top 42 thereof to form generally square projections 44.

Referring now to FIG. 5, an LED lamp 51 having an enclosure or housing 52 and leads 53 and 54 is shown. The housing defines a lens according to contemporary practice.

The advantages of the present invention include providing an LED device structure which facilitates a high yield manufacturing process, provides higher light output efficiency, provides a backside reflector to enhance on-axis luminescent intensity suitable for surface mount package, provides good thermal contact via the metallic reflector allowing fast heat removal from the LED active region that results in better LED reliability and higher current density operation, and provides opportunity for large size wafer processing up to 4″ to increase throughput and lower manufacturing cost.

It is understood that the exemplary LEDs and methods for forming the same described herein and shown in the drawings represent only presently preferred embodiments of the invention. Indeed, various modifications and additions may be made to such embodiments without departing from the spirit and scope of the invention. For example, the thicker wafer of the present invention may be used to fabricate a wide variety of electronic, photonic and other types of devices. Further, as those skilled in the art will appreciate, various crystal structures other than cubic may be utilized in the practice of the present invention.

Thus, these and other modifications and additions may be obvious to those skilled in the art and may be implemented to adapt the present invention for use in a variety of different applications.

1. A method for dicing a AlInGaN based LED wafer, the method comprising providing a transparent substrate formed of a material having a crystal structure which facilitates breaking of the AlInGaN based LED wafer in a substantially consistent and desirable manner without substantial thinning thereof.

2. The method as recited in claim 1, wherein the wafer is at least approximately 110 micrometers thick.

3. The method as recited in claim 1, wherein the wafer is between approximately 200 micrometers and approximately 300 micrometers thick.

4. The method as recited in claim 1, wherein the crystal structure facilitates the formation of die having a generally rectangular surface.

5. The method as recited in claim 1, wherein the crystal structure facilitates the formation of die having a generally square surface.

6. A method for dicing a AlInGaN based LED wafer, the method comprising:
providing a transparent substrate formed of a material having a crystal structure which tends to facilitate propagation of cracks from one flat surface to another flat surface therethrough in a manner which facilitates the formation of generally square die; and
breaking the wafer so as to form a plurality of die.

7. A method for dicing a AlInGaN based LED wafer, the method comprising providing a transparent substrate formed of a material having a crystal structure and breaking the wafer along cleavage planes of the crystal material so as to form generally square die.

8. A method for processing a AlInGaN based LED wafer, the method comprising:
providing a wafer, the wafer comprising a crystalline substrate material which has a crystal structure, the crystal structure defining at least two orthogonal cleavage planes which facilitate the formation of die having a desired geometric configuration; and
dicing the wafer.

9. The method as recited in claim 8, further comprising the step of forming a plurality of separate devices upon the wafer prior to dicing the wafer.

10. The method as recited in claim 8, wherein the crystal structure is generally cubic.

11. The method as recited in claim 8, wherein the crystal structure is face centered cubic.

12. The method as recited in claim 8, wherein the crystalline material comprises at least one of MgO, ZnO and Spinel.

13. The method as recited in claim 8, wherein at least one cleavage plane comprises a plurality of cleavage planes, the plurality of cleavage planes defining a generally rectangular pattern when projected upon a surface of the wafer.

14. The method as recited in claim 8, wherein at least one cleavage plane comprises a plurality of cleavage planes, the plurality of cleavage planes defining a generally square pattern when projected upon a surface of the wafer.

15. The method as recited in claim 8, wherein the wafer comprises a material that is substantially transparent to light.

16. The method as recited in claim 8, wherein the wafer comprises a material that is substantially transparent to at least one wavelength of visible light.

17. The method as recited in claim 8, wherein the wafer has a thickness of at least approximately 110 micrometers.

18. The method as recited in claim 8, wherein the waver has a thickness of at least approximately 200 micrometers.

19. The method as recited in claim 8, wherein the wafer has a thickness of between approximately 200 micrometers and approximately 300 micrometers.

20. The method as recited in claim 8, wherein dicing the wafer comprises mechanically scribing the wafer and breaking wafer.

21. The method as recited in claim 8, wherein dicing the wafer comprises laser scribing the wafer and breaking wafer.

22. A method for forming a AlInGaN LED, the method comprising:
providing a substrate, the substrate comprising a crystalline material which has a crystal structure, the crystal structure defining at least two generally orthogonal cleavage planes which facilitate the formation of die having a desired geometric configuration and the substrate being substantially transparent to light of at least one wavelength;
forming a plurality of separate LED structures upon the substrate; and dicing the substrate.

23. The method as recited in claim 22, wherein the substrate comprises at least one of MgO, ZnO and Spinel.

24. The method as recited in claim 22, wherein the LED is formed upon the substrate via a metal organic chemical vapor deposition process.

25. The method as recited in claim 22, further comprising packaging the LED into a lamp having leads configured to provide electrical power to the LED and having optics configured to provide a desired light emission pattern.

26. The method as recited in claim 22, further comprising forming a reflective coating on the bottom of the substrate.

27. The method as recited in claim 22, further comprising forming a reflective coating comprising a dielectric material on the bottom of the substrate.

28. The method as recited in claim 22, further comprising forming a reflective coating comprising at least one of aluminum, silver and chromium on the bottom of the substrate.

29. The method as recited in claim 22, further comprising forming a reflective coating comprising a dielectric material on the bottom of the substrate.

30. The method as recited in claim 22, further comprising forming a reflective coating on the bottom of the substrate before dicing the substrate.

31. An AlInGaN LED formed by a method comprising:
providing a AlInGaN LED wafer, the wafer comprising a crystalline substrate material which has a crystal structure, the crystal structure defining at least two cleavage planes which are generally orthogonal with respect to one another so as to facilitate the formation of die having a desired geometric configuration; and
dicing the wafer.

32. A AlInGaN LED die having a top, a bottom and a plurality of sides, the die comprising a substrate material having a crystal structure and wherein all of the sides are substantially defined by a cleavage plane of the crystal.

33. The die as recited in claim 32, wherein the sides are at a non-orthogonal angle with respect to the top.

34. An AlInGaN based device comprising:
a substrate having all sides defined substantially by cleavage planes of a crystal; and
an integrated circuit formed upon the substrate.

35. An AlInGaN based LED comprising:
a substrate comprising a crystalline material having a crystal structure, all sides of the substrate being defined by cleavage planes of the crystal structure; and
an AlInGaN p-n junction formed upon the substrate.

36. The LED as recited in claim 35, wherein the crystal structure is generally cubic.

37. The LED as recited in claim 35, wherein the crystal structure is face centered cubic.

38. The LED as recited in claim 35, wherein the crystalline material comprises at least one of MgO, ZnO and Spinel.

39. The LED as recited in claim 35, wherein the substrate comprises a material that is substantially transparent to light.

40. The LED as recited in claim 35, wherein the substrate comprises a material that is substantially transparent to at least one wavelength of visible light.

41. The LED as recited in claim 35, wherein the substrate has a thickness of at least approximately 110 micrometers.

42. The LED as recited in claim 35, wherein the substrate has a thickness of at least approximately 200 micrometers.

43. The LED as recited in claim 35, wherein the substrate has a thickness of between approximately 200 micrometers and approximately 300 micrometers.

44. The LED as recited in claim 35, further comprising a reflector formed upon the bottom of the substrate.

45. The LED as recited in claim 35, further comprising a reflector formed upon the bottom of the substrate, the reflector being formed of at least one of aluminum, silver, chromium, and a dielectric.

46. A device comprising an AlInGaN LED having a backside reflector formed upon a substrate thereof, the substrate comprising at least one of MgO, ZnO and Spinel.

47. An AlInGaN based LED comprising a substantially transparent substrate which is thicker than 110 micrometers the substrate comprising at least one of sapphire (Al2O3), Spinel, ZnO, MgO, GaN, AlN, AlGaN.

48. The LED as recited in claim 47, wherein the substrate has a thickness between approximately 200 micrometers and approximately 300 micrometers.

49. An AlInGaN based LED comprising a substantially transparent substrate which is thicker than approximately 110 micrometers and having a backside reflector formed upon the substrate, the substrate comprising at least one of sapphire (Al2O3), Spinel, ZnO, MgO, GaN, AlN, AlGaN, SiC.

50. The LED as recited in claim 49, wherein the substrate has a thickness of between approximately 200 micrometers and approximately 300 micrometers.

51. The LED as recited in claim 49, wherein the reflector comprises a metallic coating comprising at least one of Al, Ag, Cr, or dielectric mirror (Bragg reflector).

52. An AlInGaN based LED die comprising a substantially transparent substrate which is thicker than approximately 110 micrometers and wherein all sides of the die are defined by cleavage planes of the substrate material, the substrate comprising at least one of sapphire (Al2O3), Spinel, ZnO, MgO, GaN, AlN, AlGaN, SiC.

53. The LED die as recited in claim 52, wherein the substrate has a thickness between approximately 200 micrometers and approximately 300 micrometers.

54. The LED die as recited in claim 52, wherein the substrate comprises at least one of sapphire, GaN, AlN, AlGaN and SiC.

55. The LED die as recited in claim 52, wherein the geometry of the LED die is parallelogram.

56. The LED die as recited in claim 52, wherein the substrate comprises at least one of Spinel, ZnO and MgO.

57. The LED die as recited in claim 52, wherein the geometry of the LED die is rectangular.

58. The LED die as recited in claim 52, wherein the geometry of the LED die is square.

59. An AlInGaN based LED die comprising a substantially transparent substrate which is thicker than approximately 110 micrometers, the substrate having a backside reflector formed thereon, all sides of the substrate being by cleavage planes of the substrate material.

60. The LED as recited in claim 59 the substrate comprises at least one of sapphire (Al2O3), Spinel, ZnO, MgO, GaN, AlN, AlGaN, SiC.

61. The LED as recited in claim 59, wherein the substrate has a thickness between approximately 200 micrometers and approximately 300 micrometers.

62. The LED as recited in claim 59, wherein the reflector is a metallic coating comprising at least one of Al, Ag, Cr, and dielectric mirror (Bragg reflector).

63. The LED as recited in claim 59, wherein the substrate comprises at least one of sapphire, GaN, AlN, AlGaN, and SiC.

64. The LED as recited in claim 59, wherein the geometry of the LED die is parallelogram.

65. The LED as recited in claim 59, wherein the substrate comprises at least one of Spinel, ZnO, and MgO.

66. The LED as recited in claim 59, wherein the geometry of the LED die is rectangular.

67. The LED as recited in claim 59, wherein the geometry of the LED die is square.

68. A lamp comprising:
an LED having a substrate, the substrate having a thickness greater than 110 micrometers and being substantially transparent to light of at least one wavelength;
a housing generally surrounding the LED;
leads extending into the housing and configured to provide electrical power to the LED; and
optics configured to provide a desired light emission pattern.

69. A surface mount device comprising:
an LED having a substrate, the substrate having a thickness greater than 110 micrometers and being substantially transparent to light of at least one wavelength;
a casing within which the LED is substantially disposed; and
leads extending into the casing and configured to provide electrical power to the LED.

70. The surface mount device as recited in claim 69, further comprising a reflective coating formed upon the bottom of the LED.
